(19) United States
(12) Patent Application Publication
(10) Pub. No.: US 2026/0213613 A1
(43) Pub. Date: Jul. 23, 2026

(54) CIRCUIT BOARD AND FAN MOTOR COMPRISING SAME

(71) Applicant: HANON SYSTEMS, Daejeon (KR)

(72) Inventors: Byung Kuk KIM, Daejeon (KR); Chung Jae BAEK, Daejeon (KR); Sung Un SHIM, Daejeon (KR)

(21) Appl. No.: 19/138,397

(22) PCT Filed: Oct. 26, 2023
(86) PCT No.: PCT/KR2023/016699

§ 371 Date: Jun. 12, 2025

(30) Foreign Application Priority Data
Dec. 12, 2022 (KR) 10-2022-0172425

(51) Int. Cl. H02K 7/14; H02K 11/40; H05K 1/02

(52) U.S. Cl. CPC H02K 7/14; H02K 11/40; H05K 1/0215; H02K 2211/03; H05K 2201/09281

(57) ABSTRACT

Embodiments relate to a circuit board which is coupled to an external device through a coupling member and includes a conductive pattern, a first element, a first contact point at which the first element is in contact with the conductive pattern, and a second contact point in contact with the coupling member, wherein a portion of the conductive pattern is exposed toward the external device to form a third contact point, and the third contact point is in contact with the external device to which the coupling member is fastened.

### TECHNICAL FIELD

The present invention relates to a circuit board and a fan motor including the same.

### BACKGROUND ART

A fan motor may include a rotor, a stator, a shaft, a fan connected to the shaft, and a housing including the rotor and the stator. In addition, the fan motor may include a circuit board provided in the housing.

A circuit board may generate much noise such as electrostatic discharge (ESD) and electromagnetic compatibility (EMC). The generated noise may be transmitted or emitted through a power line and may adversely affect the operation of other devices.

Such noise is removed and current is discharged through a ground. However, when a path to the ground is long, there is a problem that residual noise is not removed, and when high current flows, there is a problem that an element is damaged.

Since the location of the element should be close to the ground in order to reduce the path to the ground, there is a problem of restricting a design.

### TECHNICAL PROBLEM

The present invention is intended to solve the above-described problems and directed to providing a device in which a length of a path of a chassis ground is reduced to improve noise removal performance and prevent an element of a board from being damaged.

Objects of the present invention are not limited to the above-described object, and other objects that have not been described above will be clearly understood by those skilled in the art through the following descriptions.

### TECHNICAL SOLUTION

One aspect of the present invention provides a circuit board which is coupled to an external device through a coupling member and includes a conductive pattern, a first element, a first contact point at which the first element is in contact with the conductive pattern, and a second contact point in contact with the coupling member, wherein a portion of the conductive pattern is exposed toward the external device to form a third contact point, and the third contact point is in contact with the external device to which the coupling member is fastened.

When viewed downward from above, the third contact point may be disposed to be closer to the first contact point than the second contact point.

When viewed downward from above, a length between the first contact point and the third contact point may be smaller than a length of the conductive pattern.

The second contact point and the third contact point may be disposed to be located at vertexes of a triangle.

When viewed downward from above, a length between the third contact point and the first contact point may be smaller than a shortest distance among distances between the third contact point and the second contact point.

Another aspect of the present invention provides a fan motor including a circuit board provided inside a housing, wherein the housing includes a protrusion protruding toward the circuit board, the circuit board includes a conductive pattern, a first element, a first contact point at which the conductive pattern is in contact with the first element, and a second contact point in contact with the coupling member, a portion of the conductive pattern is exposed toward the circuit board to form a third contact point, and the third contact point is in contact with the protrusion.

In the fan motor, when viewed downward from above, the third contact point may be disposed to be closer to the first contact point than the second contact point.

In the fan motor, when viewed downward from above, a length between the first contact point and the third contact point may be smaller than a length of the conductive pattern.

In the fan motor, the second contact point and the third contact point may be disposed to be located at vertexes of a triangle.

In the fan motor, a length between the third contact point and the first contact point may be smaller than a shortest distance among distances between the third contact point and the second contact point.

### ADVANTAGEOUS EFFECTS

According to an embodiment, since a portion of a conductive pattern to which a coupling member is connected is exposed at a location close to a first element to significantly reduce a length of a path for implementing chassis grounding, there is an advantage of improving robustness against noise.

According to an embodiment, there is an advantage of preventing damage to an element of a circuit board when a high current flows.

### DESCRIPTION OF DRAWINGS

FIG. 1 is a view illustrating a fan motor according to an embodiment.

FIG. 2 is a view illustrating a circuit board and a housing.

FIG. 3 is a view illustrating a conductive pattern of the circuit board for chassis grounding.

FIG. 4 is a side view illustrating a board of a first element.

FIG. 5 is a view illustrating a state in which the housing is in contact with the conductive pattern to implement chassis grounding.

FIG. 6 is a view illustrating a noise path.

### MODES OF THE INVENTION

It should be understood that, when a first component is referred to as being “connected,” “coupled,” or “linked” to a second component, such a description may include both a case in which the first component is directly connected, coupled, or linked to the second component, and a case in which the first component is connected, coupled, or linked to the second component with a third component interposed therebetween.

In addition, when a first component is described as being formed or disposed “on (above)” or “under (below)” a second component, such a description includes both a case in which the two components are formed or disposed in direct contact with each other and a case in which one or more other components are interposed between the two components. In addition, when a first component is described as being formed “on (above) or under (below)” a second component, such a description may include a case in which the first component is formed at an upper side or a lower side with respect to the second component.

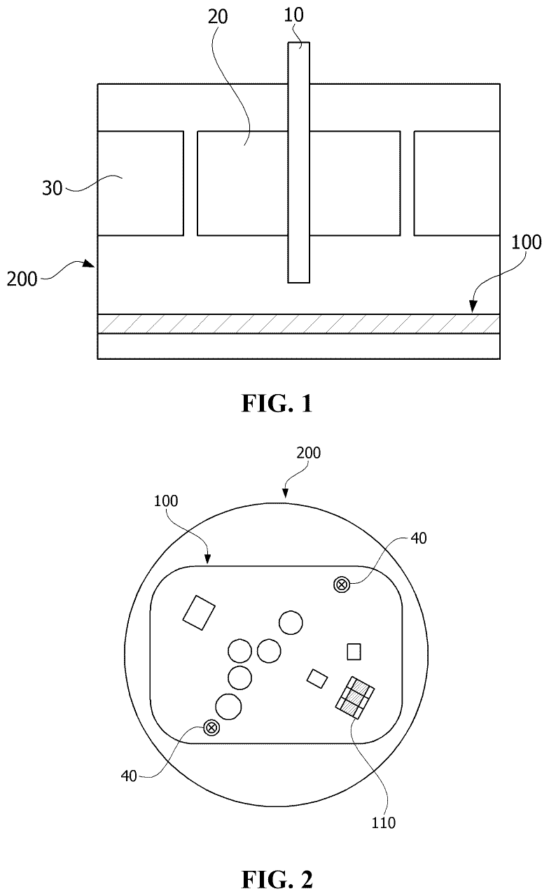

FIG. 1 is a view illustrating a fan motor according to an embodiment.

Referring to FIG. 1, the fan motor according to the embodiment may include a shaft 10, a rotor 20, a stator 30, a circuit board 100, and a housing 200.

The shaft 10 may be coupled to the rotor 20. When a current is supplied, and then an electromagnetic interaction occurs between the rotor 20 and the stator 30, the rotor 20 rotates, and the shaft 10 is rotated in conjunction with the rotation.

The rotor 20 rotates through an electric interaction with the stator 30. The rotor 20 may be disposed to correspond to the stator 30 and disposed inside the stator 30. The rotor 20 may include a rotor core and a magnet.

The stator 30 may be disposed outside the rotor 20. The stator 30 includes a coil, and the coil induces an electric interaction with the magnet of the rotor 20.

The rotor 20 and the stator 30 may be disposed in the housing 200.

In addition, the circuit board 100 may also be disposed in the housing 200.

FIG. 2 is a view illustrating the circuit board 100 and the housing 200.

Referring to FIG. 2, a first element 110 is mounted on the circuit board 100. For example, the first element 110 may be a ceramic capacitor. The ceramic capacitor is a capacitor in which ceramic or glass with a high dielectric constant is used as an insulator between two electrode plates. Since a ceramic capacitor has electrodes, which do not have polarities, and has superior temperature characteristics and high frequency characteristics, ceramic capacitors are widely used for temperature compensation or noise removal.

Meanwhile, the circuit board 100 may be coupled to the housing 200 through a bolt and a coupling member 40. A plurality of coupling members 40 may be disposed as the coupling member 40. The coupling members 40 may be disposed near an edge of the circuit board 100. Accordingly, when the first element 110 is disposed near a corner of the circuit board 100, the first element 110 may be disposed at a considerable distance from the coupling member 40. Chassis grounding of the circuit board 100 may be implemented through the coupling member 40 fastened to the housing 200.

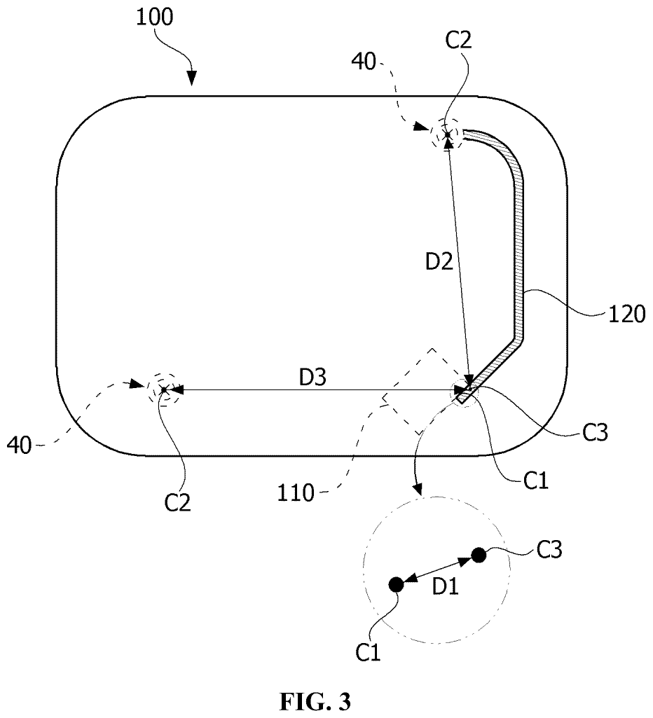

FIG. 3 is a view illustrating a conductive pattern 120 of the circuit board 100 for chassis grounding.

Referring to FIG. 3, the first element 110 and the coupling member 40 are electrically connected for the chassis grounding. On the circuit board 100, a first contact point C1 of the first element 110 and a second contact point C2 in contact with the coupling member 40 may be provided, and the conductive pattern 120 connecting the first contact point C1 and the second contact point C2 may be provided. In this case, the first contact point C1 corresponds to a point at which the conductive pattern 120 and the first element 110 are electrically connected, and the second contact point C2 corresponds to a point at which the conductive pattern 120 and the coupling member 40 are electrically connected.

As an example, when a shape of the circuit board 100 is a quadrangular shape, the second contact point C2 may be located near each of diagonally facing corners of the circuit board 100, and the first contact point C1 may be located near another corner of the circuit board 100. Accordingly, the conductive pattern 120 connecting the first contact point C1 and the second contact point C2 may be formed to extend along the edge of the circuit board 100.

Since the conductive pattern 120 is long due to locations of the first element 110 and the coupling member 40, noise increases, and it is vulnerable to electrostatic discharge (ESD).

Accordingly, in the circuit board 100 according to the embodiment, a portion of the conductive pattern 120 is exposed near the first element 110 to implement the chassis grounding with the housing 200.

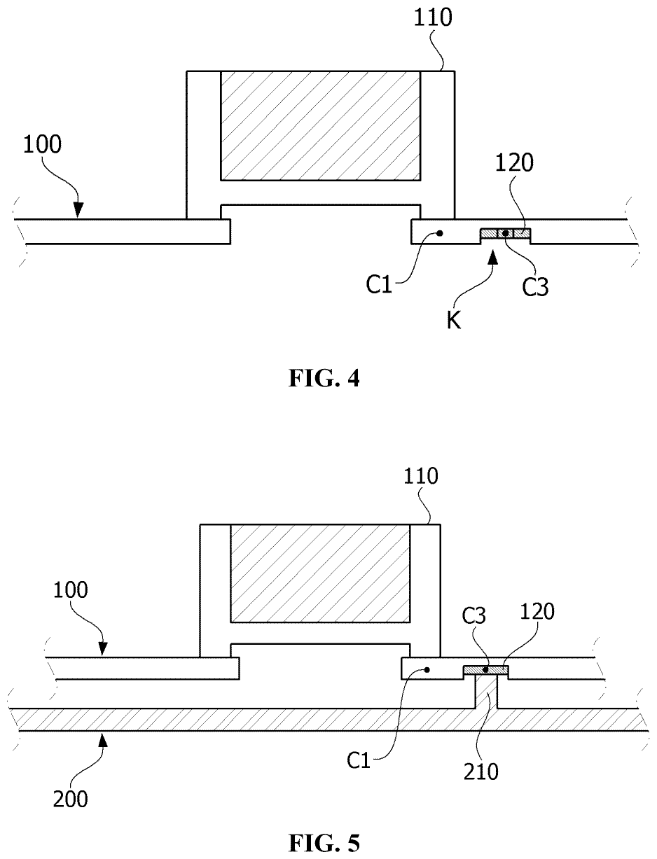

FIG. 4 is a side view illustrating a board of the first element 110.

Referring to FIGS. 3 and 4, the first element 110 is connected to the conductive pattern 120 at the first contact point C1. As illustrated in portion K of FIG. 4, a portion of the circuit board 100 is open, and the conductive pattern 120 is exposed to the outside. In this case, a lower surface of the circuit board 100 is defined as a surface facing the housing 200. A partial region of the open lower surface of the circuit board 100 is disposed close to the first element 110. This is to reduce a length of a noise path through the first element 110.

FIG. 5 is a view illustrating a state in which the housing 200 is in contact with the conductive pattern 120 to implement the chassis grounding.

Referring to FIG. 5, the housing 200 may include a protrusion 210. The protrusion 210 protrudes toward the lower surface of the circuit board 100. The protrusion 210 is in contact with the exposed conductive pattern 120 to form a third contact point C3. Accordingly, the noise path is directly formed through the third contact point C3 located near the first element 110 without reaching the coupling member 40.

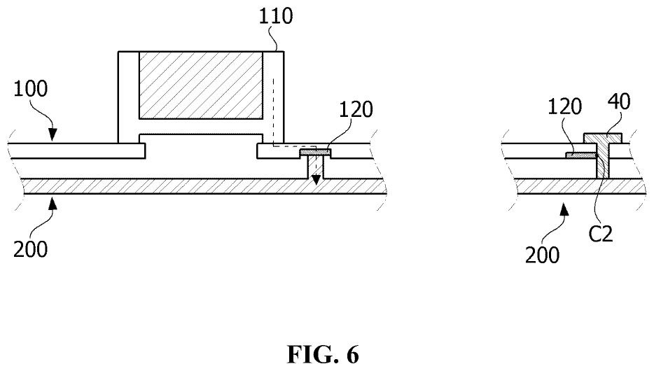

FIG. 6 is a view illustrating the noise path.

Referring to FIGS. 5 and 6, noise of the first element 110 may be directly guided to the housing 200 through the third contact point C3 before reaching the second contact point C2 of the coupling member 40.

Relative locations of the first contact point C1, the second contact point C2, and the third contact point C3 according to the locations of the first element 110 and the coupling member 40 will be described below.

When viewed downward from above as illustrated in FIG. 3, two second contact points C2 and the third contact point C3 may be disposed at vertexes of a triangle. The third contact point C3 may be disposed to be closer to the first contact point C1 than the second contact points C2. When viewed downward from above, a length D1 between the first contact point C1 and the third contact point C3 is much smaller than lengths D2 and D3 between the third contact point C3 and the second contact points C2. The length between the third contact point C3 and the first contact point C1 may be smaller than a shortest distance among the lengths between the third contact point C3 and the second contact points C2.

In addition, when viewed downward from above, the length D1 between the first contact point C1 and the third contact point C3 is smaller than a total length of the conductive pattern 120.

Since a portion of the conductive pattern 120 to which the coupling member 40 is connected is exposed at a location close to the first element 110, a path for implementing the chassis grounding is very short. Accordingly, robustness against the noise can be significantly improved.

In addition, even when a high current flows, since the high current may be discharged through the protrusion 210 of the housing 200, the circuit board 100 can prevent the element from being damaged.

The circuit board and the fan motor including the same according to one exemplary embodiment of the present invention have been specifically described above with reference to the accompanying drawings.

The above-described embodiments of the present invention should be considered in a descriptive sense only in any aspect and not for purposes of limitation, and the scope of the present invention is defined not by the detailed description but by the appended claims. In addition, it should be interpreted that the scope of the present invention encompasses all modifications and alterations derived from meanings and the scope and equivalents of the appended claims.

1. A circuit board, which is coupled to an external device through a coupling member, the circuit board comprising:
a conductive pattern;
a first element;
a first contact point at which the first element is in contact with the conductive pattern; and
a second contact point in contact with the coupling member,
wherein a portion of the conductive pattern is exposed toward the external device to form a third contact point, and
the third contact point is in contact with the external device to which the coupling member is fastened.

2. The circuit board of claim 1, wherein, when viewed downward from above, the third contact point is disposed to be closer to the first contact point than the second contact point.

3. The circuit board of claim 1, wherein, when viewed downward from above, a length between the first contact point and the third contact point is smaller than a length of the conductive pattern.

4. The circuit board of claim 1, wherein the second contact point and the third contact point are disposed to be located at vertexes of a triangle.

5. The circuit board of claim 1, wherein a length between the third contact point and the first contact point is smaller than a shortest distance among distances between the third contact point and the second contact point.

6-10. (canceled)

11. The circuit board of claim 1,
wherein the conductive pattern connecting the first contact point and the second contact point are formed to extend along the edge of the circuit board.

12. The circuit board of claim 1,
wherein a lower surface of the circuit board is defined as a surface facing the housing,
wherein a portion of the circuit board is open, and the conductive pattern is exposed to the outside

13. The circuit board of claim 1,
wherein a partial region of the open lower surface of the circuit board is disposed close to the first element.

14. A fan motor including a circuit board provided inside a housing, wherein:
the housing includes a protrusion protruding toward the circuit board;
the circuit board includes a conductive pattern, a first element, a first contact point at which the conductive pattern is in contact with the first element, and a second contact point in contact with the coupling member;
a portion of the conductive pattern is exposed toward the circuit board to form a third contact point; and
the third contact point is in contact with the protrusion.

15. The fan motor of claim 14, wherein, when viewed downward from above, the third contact point is disposed to be closer to the first contact point than the second contact point.

16. The fan motor of claim 14, wherein, when viewed downward from above, a length between the first contact point and the third contact point is smaller than a length of the conductive pattern.

17. The fan motor of claim 14, wherein the second contact point and the third contact point are disposed to be located at vertexes of a triangle.

18. The fan motor of claim 17, wherein a length between the third contact point and the first contact point is smaller than a shortest distance among distances between the third contact point and the second contact point.

19. The fan motor of claim 14,
wherein the conductive pattern connecting the first contact point and the second contact point are formed to extend along the edge of the circuit board.

20. The fan motor of claim 14,
wherein a lower surface of the circuit board is defined as a surface facing the housing,
wherein a portion of the circuit board is open, and the conductive pattern is exposed to the outside.

21. The fan motor of claim 14,
wherein a partial region of the open lower surface of the circuit board is disposed close to the first element.
